(19) United States
(12) Patent Application Publication
(10) Pub. No.: US 2012/0217823 A1
(43) Pub. Date: Aug. 30, 2012

(54) DISPLAY DEVICE AND POWER-SUPPLY NECESSITY DETERMINATION METHOD OF BRANCH DEVICE CONNECTED TO DISPLAY DEVICE

(76) Inventor: Katsuhiro Shimizu, Tokyo (JP)

(21) Appl. No.: 13/399,699

(22) Filed: Feb. 17, 2012

(30) Foreign Application Priority Data
Feb. 24, 2011 (JP) 2011-038494

(51) Int. Cl. H01H 47/00; H03K 5/153

(52) U.S. Cl. 307/130; 327/77

(57) ABSTRACT

A branch device has a connector for connecting to a display device as a sink device. A pull-up resistor is connected between an internal power source in the branch device and a first terminal in the connector when power supply from the display device is not necessary for the branch device, and a short resistor is connected between the first terminal and a second terminal in the connector when power from the display device is necessary. An evaluation circuit determines whether or not the power has to be supplied from the display device to the branch device by evaluating a voltage appearing at the first terminal when the signal for determination is applied to the second terminal by comparing that voltage to two different reference voltages which are within a range higher than a GND voltage and lower than the voltage of a second internal power source of the device itself.

### FIELD

The present disclosure relates to a display device having a video interface in Displayport standard and a power-supply necessity determination method of a branch device connected to the display device.

### BACKGROUND

There exist DisplayPort as a video interface standard for the display devices such as a monitor and a projector. DisplayPort can be used as an interface for not only internal connection between a notebook computer as a source device and a display device as a sink device but also interconnection between various devices as source devices such as a personal computer, a settop box, a media player and a game machine and the display device through a cable.

Additionally, a branch device such as a splitter, a switcher or the like is occasionally connected between the sink device and the source device. There exist a branch device operating by a power source of the device itself and a branch device operating by receiving power supply from the source device or the sink device.

In DisplayPort standard, the following regulations are provided concerning a scheme for determining whether the branch device is a device to which power has to be supplied for operation from the sink device or a device to which power does not have to be supplied from the sink device.

A. When power supply from the sink device is not necessary for the branch device, a pull-up resistor is connected to an internal power source in the branch device.

B. When power supply from the sink device is necessary for the branch device, a short resistor (<100Ω) is connected between two terminals (Pin 13, Pin 14) of a connector of the branch device.

C. When the sink device supplies probe power to the terminal (Pin 14) of the connector of the branch device and detects that the terminal (Pin 13) is “H” level, the branch device is determined to be the device to which power has to be supplied from the sink device.

D. When the sink device detects that the terminal (Pin 13) is “H” level in a state where the sink device does not supply probe power to the terminal (Pin 14) of the connector of the branch device, the branch device is determined to be the device to which power does not have to be supplied from the sink device is not necessary.

An example of related art includes “VESA DisplayPort Standard (Version 1, Revision 1a)” 3.2.1 DP_PWR User Detection Method, Page 147, [online], 11 Jan. 2008 [searched on 9 Feb. 2011], Internet [URL: http://hackipedia. org/Hardware/video/connectors/DisplayPort/VESA%20DisplayPort%20Standard%20v1.1a.pdf].

### SUMMARY

In the DisplayPort standard, at least the step of detecting the level of the terminal (Pin 13) in the state where the sink device supplies the probe power to the terminal (Pin 14) of the connector of the branch device and a step of detecting the level of the terminal (Pin 13) in the state where the sink device does not supply the probe power are necessary in the scheme for determining whether power supply from the sink device is necessary for the branch device or not, therefore, there are problems that procedures for determination will be complicated and it takes time for determination.

In view of the above, it is desirable to provide a display device capable of determining whether a connected branch device is a device to which power has to be supplied from the display device as the sink device or not in good condition with simpler procedures and a power-supply necessity determination method of the branch device connected to the display device.

An embodiment of the present disclosure is directed to a display device including a second connector which can be connected to a first connector of a branch device having the first connector for connecting to a display device as a sink device, in which a pull-up resistor is connected between a first internal power source in the branch device and a first terminal predetermined in the first connector when power supply from the display device is not necessary for the branch device, and a short resistor is connected between the first terminal and a second terminal predetermined in the first connector when power supply from the display device is necessary, a determination signal supply circuit applying a signal for determination to the second terminal of the connected branch device, and a level evaluation circuit determining whether the branch device is a device to which power has to be supplied from the display device or not by evaluating a voltage appearing in the first terminal at the time of applying the signal for determination to the second terminal by comparison with two types of reference voltages which are different to each other set in advance within a range higher than a GND voltage and lower than a voltage of a second internal power source of the device itself.

In the embodiment of the present disclosure, it is possible to uniquely determine whether the connected branch device is a device to which power has to be supplied from the display device or not by evaluating the voltage appearing in the first terminal by comparison with two types of reference voltages which are different to each other set in advance within the range higher than the GND voltage and lower than the voltage of the second internal power source of the device itself by the level evaluation circuit.

In the embodiment of the present disclosure, the level evaluation circuit may determine that the branch device is the device to which power has to be supplied from the display device when the voltage appearing in the first terminal is within a range of two types of reference voltages, and may determine that the branch device is the device to which power does not have to be supplied from the display device when the voltage in the first terminal is out of the range of two types of reference voltages, and the display device may further includes a first voltage dividing resistor forming a first resistance voltage dividing circuit in cooperation with the short resistor, which sets the voltage appearing in the first terminal at the time of applying the determination signal to the second terminal to the range of two types of reference voltages when the short resistance is connected and a second voltage dividing resistor forming a second resistance voltage dividing circuit in cooperation with the first voltage dividing resistor, which sets the voltage appearing in the first terminal at the time of applying the determination signal to the second terminal so as to be out of the range of two types of reference voltages when the first internal power source in the branch device is ON as well as the pull-up resistor is connected. Accordingly, it is possible to evaluate the voltage appearing in the first terminal more positively by comparison with two types of reference voltages.

In the embodiment of the present disclosure, the display device may further includes a switch unit switching ON/OFF of the power supply to the connected branch device, in which the level evaluation circuit may supply a first switch control signal for turning on the power supply to the branch device to the switch unit when the voltage appearing in the first terminal is within the range of two types of reference voltages, and may supply a second switch control signal for turning off the power supply to the branch device to the switch unit when the voltage in the first terminal is out of the range of two types of reference voltages.

In the embodiment of the present disclosure, the display device may further include a delay circuit provided between the level evaluation circuit and the switch unit. Accordingly, when the voltage in the first terminal fluctuates largely such as from “H” level (approximately a Vcc level) to “L” level (approximately a GND level) at the time of connection/disconnection of the branch device or switching of power ON/OFF of the branch device, fluctuation components can be eliminated from the output of the level evaluation circuit, which can improve reliability.

In the embodiment of the present disclosure, the level evaluation circuit may include a buffer circuit for preventing voltage variation of the first terminal due to leak current. Accordingly, malfunction of the level evaluation circuit due to leak current can be prevented, which can improve reliability.

In the embodiment of the present disclosure, the display device may further include a control unit controlling the determination signal supply circuit to stop the supply of the determination signal at the transition from a power-on state to a stand-by state, and controlling the determination signal supply circuit to restart the supply of the determination signal at the transition from the stand-by state to the power-on state. Accordingly, it is possible to stop wasteful power supply from the display device to the branch device when the branch device or the source device is in a nonoperational state.

Another embodiment of the present disclosure is directed to a power-supply necessity determination method of a branch device connected to the display device including connecting the display device to a first connector of the branch device having the first connector for connecting to the display device as a sink device, in which a pull-up resistor is connected between a first internal power source in the branch device and a first terminal predetermined in the first connector when power supply from the display device is not necessary for the branch device, and a short resistor is connected between the first terminal and a second terminal predetermined in the first connector when power supply from the display device is necessary, applying a signal for determination from the display device to the second terminal of the connected branch device, taking a voltage appearing in the first terminal into a level evaluation circuit in the display device and determining whether the branch device is a device to which power has to be supplied from the display device or not by evaluating the voltage in the first terminal by comparison with two types of reference voltages which are different to each other set in advance within a range higher than a GND voltage and lower than a voltage of a second internal power source of the device itself.

According to the embodiments of the present disclosure, it is possible to determine whether the connected branch device is a device to which power has to be supplied from the display device as a sink device or not in good condition with simpler procedures, and reliability can be improved.

### BRIEF DESCRIPTION OF THE DRAWINGS

FIG. 1 is a diagram showing a configuration of a DisplayPort connection portion between a display device applying a typical determination method and a branch device connected thereto;

FIG. 2 is a flowchart showing determination procedures by the typical display device of FIG. 1;

FIG. 3 is a diagram showing a configuration of a DisplayPort connection portion between a display device according to the first embodiment and a branch device connected thereto;

FIG. 4 is a flowchart showing control procedures of the display device according to the first embodiment;

FIG. 5 is a diagram showing a configuration of a DisplayPort connection portion between a display device according to the second embodiment and a branch device connected thereto;

FIG. 6 is a diagram showing a configuration example of a delay circuit of FIG. 5;

FIG. 7 is a diagram showing a configuration of a DisplayPort connection portion between a display device according to a third embodiment and a branch device connected thereto;

FIG. 8 is a diagram showing a configuration example of a buffer circuit of FIG. 7;

FIG. 9 is a flowchart showing determination procedures of a modification example 1; and

FIG. 10 is a flowchart showing determination procedures of a modification example 2.

### DETAILED DESCRIPTION

Before explaining embodiments of the present disclosure, a typical method of determining whether a branch device connected to a display device as a sink device is device to which power has to be supplied from the display device or not will be explained.

### [Typical Determination Method]

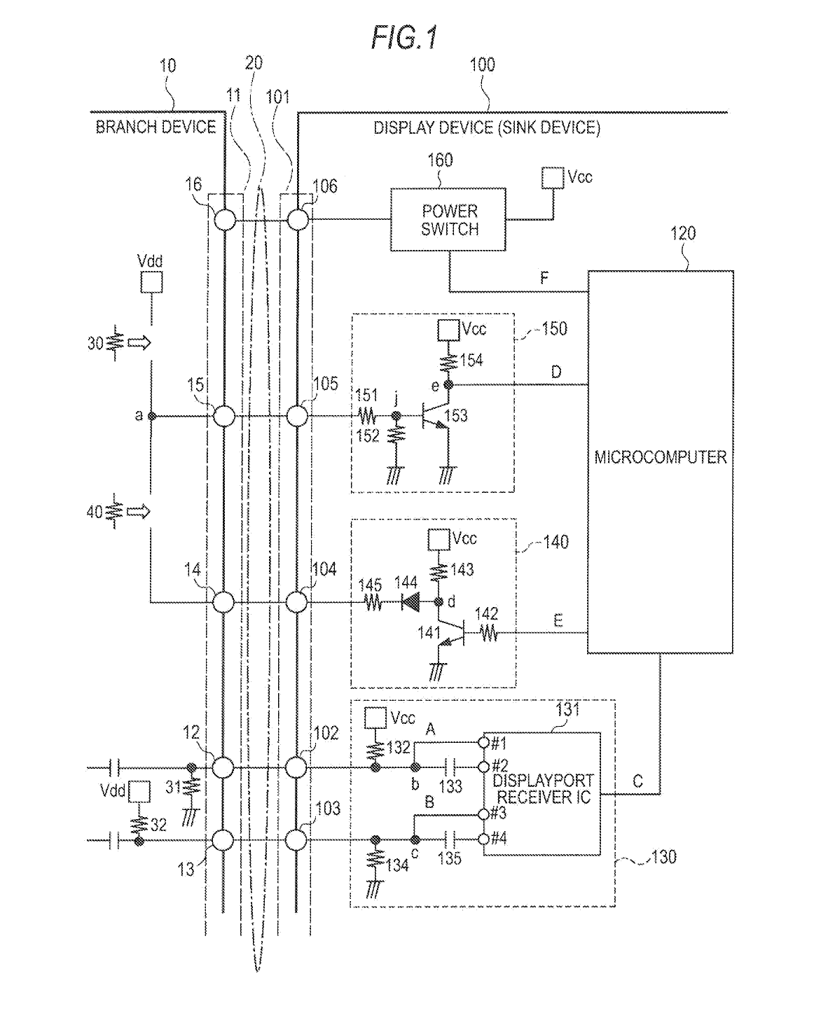

FIG. 1 is a diagram showing a configuration of a DisplayPort connection portion between a display device 100 applying a typical determination method and a branch device 10 connected thereto.

The branch device 10 is a device capable of supplying digital contents, which is, for example, a splitter, a switcher or the like connected between a source device such as a personal computer, a settop box, a media player or a game machine and a sink device. The display device 100 is a device capable of performing processing of visualizing digital video, which is, for example, a monitor, a projector or the like. The branch device 10 and the display device 100 are connected through a cable 20 at respective connectors 11 and 101 with each other.

The respective connectors 11 and 101 of the branch device 10 and the display device 100 includes terminals 12 and 102 for detecting connection of the branch device 10, terminals 13 and 103 for checking power ON/OFF of the branch device 10, terminals 14 and 104 for applying a signal for determination from the display device 100 to the branch device 10, terminals 15 and 105 as monitoring targets of voltage for obtaining determination results and terminals 16 and 106 for supplying power from the display device 100 to the branch device 10. Here, the terminal 14 of the branch device 10 corresponds to a Pin 13 of the connector in the DisplayPort standard and the terminal 15 of the branch device 10 corresponds to a Pin 14 of the connector in the DisplayPort standard. Each of the connectors and 101 includes plural terminals (not shown) for transmitting a data signal and other control signals in addition to the above terminal group.

When power supply from the sink device is not necessary for the branch device 10, a pull-up resistor 30 (for example, 100 kΩ)) is connected between an internal power source Vdd of the branch device 10 and the terminal 15.

When power supply from the display device 100 is necessary for the branch device 10, a short resistor 40 (<100 kΩ) is connected between the terminal 14 and the terminal 15.

### [Configuration of a Display Device 100 Applying the Typical Determination Method]

The display device 100 as a sink device includes a microcomputer 120, a device connection/power ON detection unit 130, a determination signal supply circuit 140, an H-level signal detection circuit 150 and a power switch 160.

### (Device Connection/Power ON Detection Unit 130)

The device connection/power ON detection unit 130 includes a DisplayPort receiver IC 131, a pull-up resistor 132, a first capacitor 133, a pull-down resistor 134 and a second capacitor 135.

One terminal of the pull-up resistor 132 is connected between a terminal #1 of the DisplayPort receiver IC 131 and the terminal 102 of the connector 101 of the display device 100. The other terminal of the pull-up resistor 132 is connected to an internal power source Vcc of the display device 100. A connection point “b” between the pull-up resistor 132 and the terminal #1 of the DisplayPort receiver IC 131 is connected to a terminal #2 of the DisplayPort receiver IC 131 through the first capacitor 133. On the other hand, one terminal of the pull-down resistor 31 is connected to the terminal 15 of the connector 11 of the branch device 10. The other terminal of the pull-down resistor 31 is connected to GND.

The detection of connection to the branch device 10 by the device connection/power ON detection unit 130 is performed in the following manner. Note that the voltage of the internal power source Vcc of the display device 100 is approximately the same as the internal power source Vdd of the branch device 10. The DisplayPort receiver IC 131 measures a potential of the terminal #1 as a connection detection signal A. When the branch device 10 is not connected to the display device 100, the potential of the terminal #1 is a voltage value of the internal power source Vcc of the display device 100. When the branch device 10 is connected to the display device 100, electric current flows from the internal power source Vcc of the display device 100 to GND through the pull-up resistor 132, the terminal 102, the terminal 12 and the pull-down resistor 31. Accordingly, the voltage value of the terminal #1, namely, the level of the connection detection signal A is reduced. The DisplayPort receiver IC 131 detects that the branch device 10 has been connected to the display device 100 by the level of the connection detection signal A. The above is the operation of detecting connection of the branch device 10 by the device connection/power ON detection unit 130.

One terminal of the pull-down resistor 134 is connected between a terminal #3 of the DisplayPort receiver IC 131 and the terminal 103 of the connector 101 of the display device 100. The other terminal of the pull-down resistor 134 is connected to GND. The pull-down resistor 134 and the terminal #3 are connected to each other at a connection point “c”. On the other hand, one terminal of a pull-up resistor 32 is connected to the terminal 13 of the connector 11 of the branch device 10. The other terminal of the pull-up terminal 32 is connected to the internal power source Vdd of the branch device 10.

The detection of the power ON of the branch device 10 by the device connection/power ON detection unit 130 is performed in the following manner. The DisplayPort receiver IC 131 measures a potential of the terminal #3 as a power ON detection signal B. In the case where the internal power source Vdd of the branch device 10 is not turned on, the potential of the terminal #3 is approximately “0 (zero)” even when the branch device 10 is connected to the display device 100. In the case where the internal power source Vdd of the branch device 10 is turned on while the branch device 10 is connected to the display device 100, electric current flows to GND from the internal power source Vdd of the branch device 10 through the pull-up resistor 32, the terminal 13, the terminal 103 and the pull-down resistor 134. Accordingly, when a resistance value of the pull-up resistor 32 is R1 and a resistance value of the pull-down resistor 134 is R2, the potential of the terminal #3 is Vddx(R2/(R1+R2)) and the level of the power ON detection signal B is increased. The DisplayPort receiver IC 131 determines that the power of the branch device 10 is ON when the level of the power ON detection signal B is equal to or higher than a threshold value, and determines that the power of the branch device 10 is in the OFF state when the signal is lower than the threshold value.

Then, the DisplayPort receiver IC 131 notifies the microcomputer 120 of information indicating whether the branch device 10 is connected to the display device 100 or not and information indicating whether the power of the connected branch device 10 is ON or not by a communication C.

### (Determination Signal Supply Circuit 140)

The determination signal supply circuit 140 includes a transistor 141, a base resistor 142, a pull-up resistor 143, a diode 144, a protection resistor 145 and the like.

A base of the transistor 141 is connected to a determination control signal output terminal (not shown) of the microcomputer 120 through the base resistor 142. A collector of the transistor 141 is connected to the internal power source Vcc through the pull-up resistor 143 and an emitter thereof is connected to GND. A connection point “d” between the collector of the transistor 141 and the pull-up resistor 143 is connected to the terminal 104 of the connector 101 through a series circuit including the diode 144 and the protection resistor 145. An anode of the diode 144 is connected to the connection point “d”. The diode 144 works so as to prevent electric current from flowing into the display device 100 from the branch device 10, for example, when the internal power source Vcc of the display 100 is OFF.

When a determination control signal E is “H” level, the diode 144 is in a non-conductive state as the transistor 141 is turned on. When the determination control signal E is “L” level, the transistor 141 is turned off. Accordingly, when the short resistor 40 is connected to the branch device 10, a signal for determination flows from the internal power source Vcc of the display device 100 in a route of the pull-up resistor 143, the diode 144, the protection resistor 145, the terminal 104, the terminal 14, the short resistor 40, the terminal 15, the terminal 105, a protection resistor 151, a pull-down resistor 152 and GND in the H-level signal detection circuit 150.

### (H-Level Signal Detection Circuit 150)

H-level signal detection circuit 150 includes the protection resistor 151, the pull-down resistor 152, a transistor 153 and the pull-down resistor 154.

The protection resistor 151 is connected between the terminal 105 of the connector 101 and a base of the transistor 153. A connection point “j” between the protection resistor 151 and the base of the transistor 153 is connected to GND through the pull-down resistor 152. A collector of the transistor 153 is connected to the internal power source Vcc through the pull-up resistor 154 and an emitter thereof is connected to GND. Moreover, a connection point “e” between the collector of the transistor 153 and the pull-up transistor 154 is connected to a determination signal input terminal (not shown) of the microcomputer 120.

When the signal for determination flows in the route of the pull-up resistor 143, the diode 144, the protection resistor 145, the terminal 104, the terminal 14, the short resistor 40, the terminal 15, the terminal 105, the protection resistor 151, the pull-down resistor 152 and GND in the H-level signal detection circuit 150, a determination signal D supplied from the connection point “e” to the determination signal input terminal (not shown) of the microcomputer 120 will be “L” level as the transistor 153 is turned on. The determination signal D in “L” level is inputted to the microcomputer 120 as the transistor 153 is turned on also when the signal flows in a route from the internal power source Vdd of the branch device 10 to the pull-up resistor 30, the terminal 15, the terminal 105, the protection resistor 151, the pull-down resistor 152 and GND. In other cases, the level of the determination signal D supplied from the connection point “e” to the terminal signal input terminal (not shown) of the microcomputer 120 will be “H” level as the transistor 153 is turned off.

### (Microcomputer 120)

In the state where the determination control signal E is “H” level, the microcomputer 120 performs control to turn a power switch control signal F to “L” level when the determination signal D is “L” level, and performs control so that the determination control signal E is switched from “H” level to “L” level when the determination signal D is “H” level. In the state where the determination control signal E is “L” level, the microcomputer 120 performs control to turn the power switch control signal F to “H” level when the determination signal D is “L” level, and performs control to turn the power switch control signal F to “L” level when the determination signal D is “H” level.

### (Power Switch 160)

The power switch 160 turns off the power supply to the branch device 10 when the power switch control signal F in “L” level is inputted from the microcomputer 120 and turns on the power supply to the branch device 10 when the power switch control signal F in “H” level is inputted from the microcomputer 120.

### [Typical Determination Procedures]

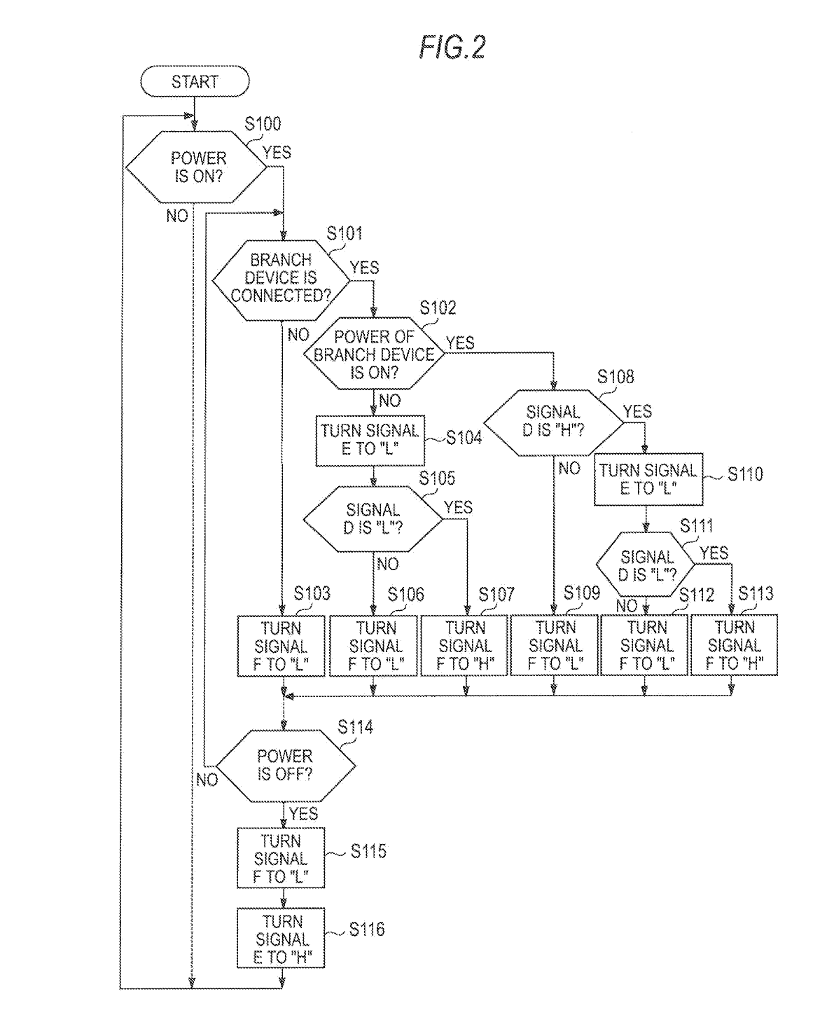

FIG. 2 is a flowchart showing determination procedures by a typical display device.

In an initial state, the determination control signal E is “H” level.

First, the microcomputer 120 allows the device connection/power ON detection unit 130 to execute the detection of connection to the branch device 10 and the detection of power ON/OFF of the branch device 10 when the power (internal power source Vcc) of the display device 100 is turned on (Y in Step S100). The device connection/power ON detection unit 130 notifies the microcomputer 120 of respective detection results.

When the branch device 10 is not connected (N in Step S101), the microcomputer 120 outputs the power switch control signal F in “L” level to the power switch 160 (Step S103). The power switch 160 receives the power switch control signal F in “L” level and turns off the power supply to the branch device 10. On the other hand, when the branch device 10 is connected (Y in Step S101), the microcomputer 120 performs different processing as described below according to ON/Off of the power of the branch device 10.

When the power of the branch device 10 is OFF (N in Step S102), the microcomputer 120 turns the determination control signal E to “L” level (Step S104). Next, the microcomputer 120 checks the level of the determination signal D of the H-level signal detection circuit 150. Here, the determination signal D is “H” level in a state where the short resistor 40 is not connected to the branch device 10. In this case (N in Step S105), the microcomputer 120 turns the power switch control signal F to “L” level so that power is not supplied to the branch device 10 (Step S106). On the other hand, when the short resistor 40 is connected to the branch device 10, the determination signal D will be “L” level. In this case (Y in Step S105), the microcomputer 120 turns the power switch control signal F to “H” level so that power is supplied to the branch 10 (Step S107).

When the power of the branch device 10 is ON (Y in Step S102), the microcomputer 120 checks the determination signal D of the H-level signal detection circuit 150 while the determination control signal E is maintained to be in “H” level (Step S108). When the power of the branch device 10 is ON as well as the pull-up resistor 30 is connected to the branch device 10, the determination signal D is “L” level. In this case (N in Step S108), the microcomputer 120 turns the power switch control signal F to “L” level so that power is not supplied to the branch device 10 (Step S109). On the other hand, when the pull-up resistor 30 is not connected to the branch device 10, the determination signal D is “H” level even when the power of the branch device 10 is ON. In this case (Y in Step S108), the microcomputer 120 turns the determination control. signal E to “L” level (Step S110). After that, the microcomputer 120 checks the determination signal D of the H-level signal detection circuit 150 again (Step S111). When the determination signal D is “H” level (N in Step S111), the microcomputer 120 turns the power switch control signal F to “L” level so that power is not supplied to the branch device 10 (Step S112). When the determination signal D is “L” level (Y in Step S111), the microcomputer 120 turns the power switch control signal F to “H” level so that power is supplied to the branch device 10 (Step S113).

When the power of the display device 100 is turned off (N in Step S114), the microcomputer 120 turns the power switch control signal F to “L” level and turns the determination control signal E to the initial “H” level (Step S115 and Step S116).

### (When Both of the Pull-Up Resistor 30 and the Short Resistor 40 are Connected)

As an exceptional case, a case where the pull-up resistor 30 and the short resistor 40 are connected to the branch device 10 can be considered. In this case, the control may be performed so that power is supplied to the branch device 10 through the power switch 160 by the microcomputer 120. Accordingly, a resistance value of the pull-up resistor 143 of the determination signal supply circuit 140 is set to be sufficiently higher than a resistance value of the pull-up resistor 30 of the branch device 10. Therefore, when the power of the branch device 10 is OFF, the transistor 153 is not turned on even when the determination control signal E is turned to “L” level, and the determination signal D is maintained to be in “H” level. Accordingly, the microcomputer 120 correctly determines that power supply is not necessary for the branch device 10, supplying the power switch control signal F in “L” level to the power switch 160 as well as switching the determination control signal E from “L” level to the initial “H” level.

In the case where the diode 144 of the determination signal supply circuit 140 does not exist, the branch device 10 sets a resistance value of the protection resistor 145 of the determination signal supply circuit 140 is set to be slightly higher than the resistance value of the pull-up resistor 30 of the branch device 10, as a result, the transistor 153 is turned on and the determination signal D is turned to “L” level when the power of the branch device 10 is ON. Accordingly, the microcomputer 120 can correctly determine that power supply is not necessary for the branch device 10 in the same manner as in the case where the power of the branch device 10 is OFF. The diode 144 of the determination signal supply circuit 140 is provided for avoiding uncertainty in operations due to the difference of resistance values between the pull-up resistor 30 and the protection resistor 145 when the resistance value of the pull-up resistor 30 is assumed to be sufficiently high.

In the case where the power of the branch device 10 is ON in a state where power is not supplied from the display device 100 to the branch device 10, it is possible to determine that power supply from the display device 100 is not necessary, therefore, the above series of determination processing can be omitted.

### First Embodiment

In the typical display device 100, it is necessary that the microcomputer 120 executes the complicated procedures as shown in FIG. 2 for setting the state of ON/OFF of the power switch 160. A first embodiment of the present disclosure can eliminate such complicated procedures.

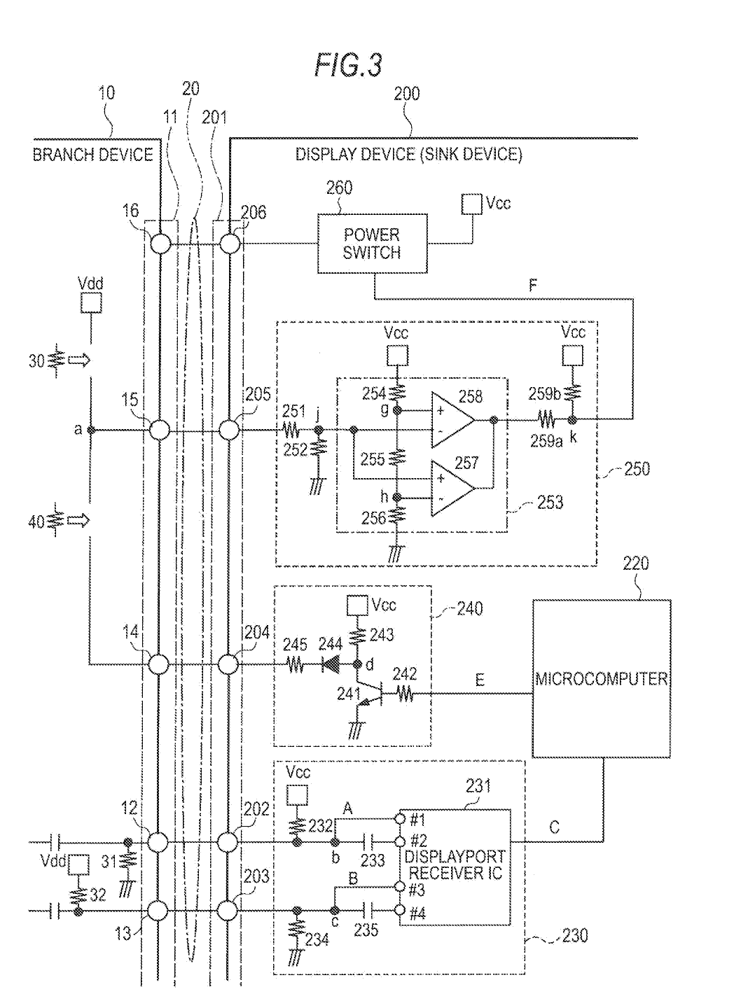

FIG. 3 is a diagram showing a configuration of a DisplayPort connection portion between a display device according to the first embodiment and a branch device connected thereto.

The configuration of the branch device 10 is the same as the typical example of FIG. 1, and part of configuration of a display device 200 is different from the typical example of FIG. 1. Configurations of other portions of the display device 200 are the same as the typical example of FIG. 1. In the display device 200 shown in the same drawing, corresponding codes in the 200s are given to the same portions as the typical example of FIG. 1.

In the display device 200 according to the embodiment, points different from the display device 100 of the typical example are as follows.

1. Level evaluation circuit 250 (configuration substituted for the H-level signal detection circuit 150 of FIG. 1)

2. Control procedures of the microcomputer 220

First, the configuration of the level evaluation circuit 250 will be explained.

### 1. Configuration of the Level Evaluation Circuit 250

The level evaluation circuit 250 includes a protection resistor 251, a pull-down resistor 252, a window comparator 253, a protection resistor 259a and a pull-up resistor 259b.

The protection resistor 251 is connected between a terminal 205 of a connector 201 and the window comparator 253. A connection point “j” between the protection resistor 251 and the window comparator 253 is connected to GND through the pull-down resistor 252.

The window comparator 253 includes a voltage dividing resistor 254, a voltage dividing resistor 255 and a voltage dividing resistor 256 connected in series between the internal power source Vcc and GND, a first comparator 257 and a second comparator 258. A connection point “g” between the voltage dividing resistor 254 and the voltage dividing resistor 255 is connected to a positive input terminal of the second comparator 258. A negative input terminal of the second comparator 258 is connected to a connection point “j” between the protection resistor 251 and the pull-down resistor 252. On the other hand, a connection point “h” between the voltage dividing resistor 255 and the voltage dividing resistor 256 is connected to a negative input terminal of the first comparator 257. A positive input terminal of the first comparator 257 is connected to the connection point “j” between the protection resistor 251 and the pull-down resistor 252.

Output terminals of the first comparator 257 and the second comparator 258 are connected at a connection point “i” between them. The connection point “i” is connected to a power switch 260 through the protection resistor 259a as well as a connection point “k” between the protection resistor 259a and the power switch 260 is connected to the internal power source Vcc through the pull-up resistor 259b.

The window comparator 253 evaluates the voltage of the connection point “j” (voltage at a first terminal) between the protection resistor 251 and the pull-down resistor 252 by comparison with two types of reference voltages generated by using three voltage dividing resistor 254, 255 and 256. That is, when resistance values of the voltage dividing resistor 254, the voltage dividing resistor 255 and the voltage dividing resistor 256 are R1, R2 and R3 respectively, the output of the first comparator 257 will be “H” level when the voltage of the connection point “j” to be evaluated is higher than “Vcc (R3/(R1+R2+R3)” which is a first reference voltage and will be “L” level in other cases. On the other hand, the output of the second comparator 258 will be “H” level when “Vcc (R2+R3)/(R1+R2+R3)) which is a second reference voltage is higher than the voltage of the connection point “j” to be evaluated and will be “L” level in other cases. Two outputs of the first comparator 257 and the second comparator 258 make a wired OR. Therefore, when both of the two outputs of the first comparator 257 and the second comparator 258 are “H” level, the output of the window comparator 253 will be “H” level and will be “L” level in other cases.

In the window comparator 253, respective resistance values R1, R2 and R3 of the voltage dividing resistor 254, the voltage dividing resistor 255 and the voltage dividing resistor 256 can be, for example, in common. In this case, the first reference voltage is “Vcc (⅓)” and the second reference voltage is “VCC (⅔)”.

A resistance value of the pull-down resistor 252 of the level evaluation circuit 250 is set to be sufficiently higher than the resistance value of the pull-up resistor 30 of the branch device 10. Accordingly, a voltage approximately the same as the voltage of the internal power source Vdd of the branch device 10 is applied to the window comparator 253 when the pull-up resistor 30 is connected to the branch device 10 as well as the power of the branch device 10 is ON. That is, the pull-up resistor 30 and the pull-down resistor 252 (second voltage dividing resistor) work as a resistance voltage dividing circuit (second resistance voltage dividing circuit) for setting the input voltage to the window comparator 253 to approximately “Vdd” when the pull-up resistor 30 is connected to the branch device 10 as well as the power of the branch device 10 is ON.

As the resistance value of the pull-down resistor 252 of the level evaluation circuit 250 is the same as the resistance value of the pull-up resistor 243 of a determination signal supply circuit 240, a voltage of approximately “Vcc (½)” is applied to the window comparator 253 as an input voltage when the short resistor 40 is connected to the branch device 10. That is, the pull-down resistor 252 (second voltage dividing resistor) and the pull-up resistor 243 (first voltage dividing resistor) work as a resistance voltage dividing circuit (first resistance voltage dividing circuit) for setting the input voltage to the window comparator 253 to approximately “Vcc (½)” when the short resistor 40 is connected to the branch device 10.

The output of the window comparator 253 is supplied to the power switch 260 as the power switch control signal F.

The power switch 260 turns off the power supply to the branch device 10 when the power switch control signal F in “L” level is inputted by the window comparator 253 and turns on the power supply to the branch device 10 when the power switch control signal F in “H” level is inputted.

### [2. Control Procedures of the Microcomputer 220]

Next, control procedures of the microcomputer 220 in the display device 200 will be explained.

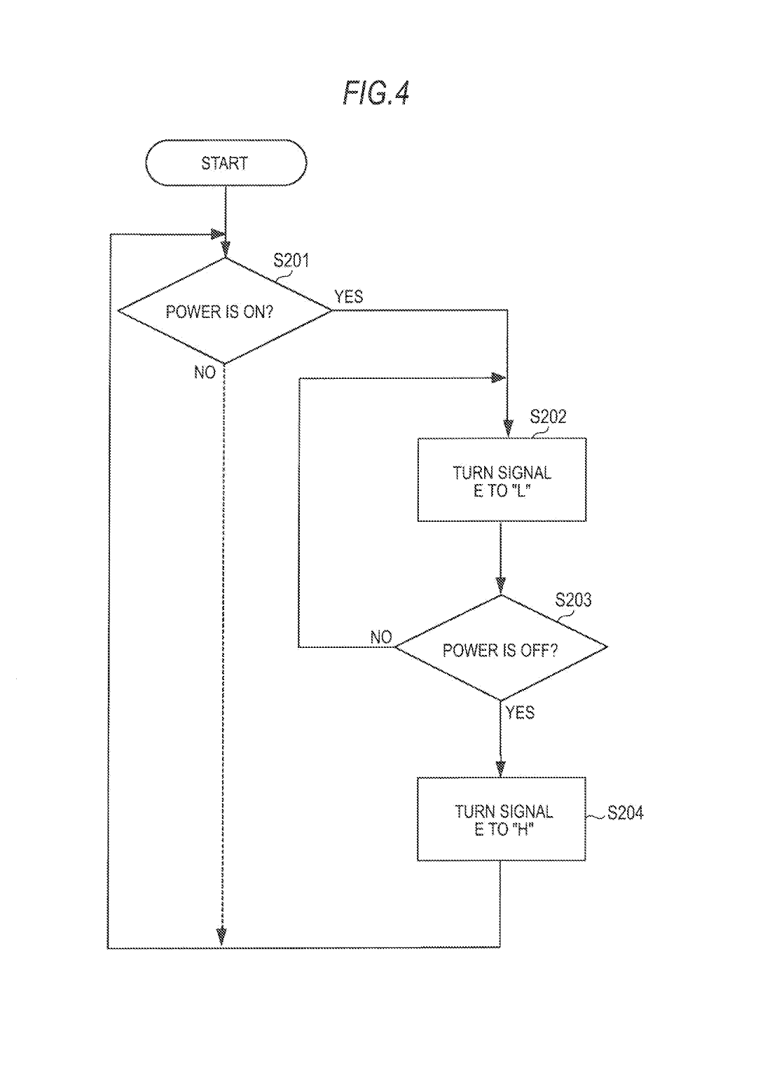

FIG. 4 is a flowchart showing control procedures of the microcomputer 220.

The control procedures of the microcomputer 220 in the case of the embodiment are extremely simple as compared with the above-described typical example.

In the initial state, the level of the determination control signal E is “H”.

First, the microcomputer 220 allows the device connection/power ON detection unit 230 to detect whether the branch device 10 is connected or not when the power of the display device 200 is turned on (Y in Step S201). The device connection/power ON detection unit 230 notifies the microcomputer 220 of the detection result by the communication C. To allow the device connection/power ON detection unit 230 to detect whether the power of the connected branch device 10 is ON or to allow the device connection/power ON detection unit 230 to acquire the detected result are not necessary in the present embodiment.

Subsequently, the microcomputer 220 switches the level of the determination control signal E from “H” to “L” (Step S202). Then, the microcomputer 220 detects that the power of the display device 200 is turned off (Y in Step S203), the microcomputer 220 switches the level of the determination control signal E from “L” to “H” (Step 5204) after that.

The above is the control procedures of the microcomputer 220.

[Operations after the Level of the Determination Control Signal E is Switched to “L”]

Next, operations performed when the display device 200 sets ON/OFF of the power supply to the branch device 10 will be explained on the assumption that a voltage appearing in the connection point “j” (input voltage to the window comparator 253) when the first reference voltage is “Vcc (⅓), the second reference voltage is “Vcc (⅔)”, the power of the branch device 10 is ON and the pull-up resistor 30 is connected is “Vdd” and a voltage appearing in the connection point “j” when the short resistor 40 is connected to the branch device 10 is “Vcc (½)”.

The explanation of operations will be made in order concerning the following states.

1. A case where the power of the branch device 10 is OFF and the pull-up resistor 30 is connected

2. A case where the power of the branch device 10 is OFF/ON and the short resistance 40 is connected

3. A case where the power of the branch device 10 is ON and the pull-up resistor 30 is connected

4. A case where both of the pull-up resistor 30 and the short resistor 40 are connected

5. A case where the branch device 10 is not connected

6. A case where the power of the branch device 10 is ON/OFF and neither of the pull-up resistor 30 and the short resistor 40 is connected

(1. A Case where the Power of the Branch Device 10 is OFF and the Pull-Up Resistor 30 is Connected)

When the power of the branch device 10 is OFF, the potential of the connection point “j”, namely, the input voltage of the window comparator 253 is the level of approximately “GND”, even when the pull-up resistor 30 is connected to the branch device 10.

Accordingly, the output of the second comparator 258 is “H” level as GND is lower than the second reference voltage (Vcc (⅔)), however, the output of the first comparator 257 is “L” level as GND is lower than the first reference voltage (Vcc (⅓)), and the power switch control signal F as the output of the window comparator 253 is “L” level. As a result, the power supply to the branch device 10 in the power switch 260 will be in the OFF state.

(2. A Case where the Power of the Branch Device 10 is ON/OFF and the Short Resistance 40 is Connected)

When the short resistor 40 is connected to the branch device 10, the input voltage to the window comparator 253 is “Vcc (½)”.

Accordingly, the output of the first comparator 257 is “H” level as Vcc (½) is higher than the first reference voltage (Vcc (⅓)), as well as the output of the second comparator 258 is “H” level as the Vcc (½) is lower than the second reference voltage (Vcc (⅔)), and the power switch control signal F as the output of the window comparator 253 is “H” level. As a result, the power supply to the branch device 10 in the power switch 260 will be in the ON state.

(3. A Case where the Power of the Branch Device 10 is ON and the Pull-Up Resistor 30 is Connected)

When the power of the branch device 10 is ON and the pull-up resistor 30 is connected, the output of the second comparator 258 is “L” level as “Vdd” is higher than the second reference voltage (Vcc (⅔)), and the power switch control signal F as the output of the window comparator 253 is “L” level. As a result, the power supply to the branch device 10 in the power switch 260 will be in the OFF state.

(4. A Case where Both of the Pull-Up Resistor 30 and the Short Resistor 40 are Connected)

A case where both of the pull-up resistor 30 and the short resistor 40 are connected to the branch device 10 will be explained as an exceptional case. The resistance value of the pull-down resistor 252 of the level evaluation circuit 250 is set to be sufficiently higher than the resistance value of the pull-up resistor 30. Therefore, in the case where the power of the branch device 10 is OFF, the output of the first comparator 257 is “L” level as the input voltage is lower than the first reference voltage (Vcc (⅓)) when the determination control signal E is “L” level, and the power switch control signal F as the output of the window comparator 253 is “L” level. As a result, the power supply to the branch device 10 in the power switch 260 will be in the OFF state.

In the case where both of the pull-up resistor 30 and the short resistor 40 are connected to the branch device 10 as well as the power of the branch device 10 is ON, the output of the second comparator 258 is “L” level as Vdd is higher than the second reference voltage (Vcc (⅔)) when the determination control signal E is “L” level, and the output of the power switch control signal F as the output of the window comparator 253 is “L” level. As a result, the power supply to the branch device 10 in the power switch 260 will be in the OFF state also in this case.

Further more, when the determination control signal E is “H” level, the output of the first comparator 257 is “L” level as the input voltage is lower than the first reference voltage (Vcc (⅓)), and the power switch control signal F as the output of the window comparator 253 is “L” level. As a result, the power supply to the branch device 10 in the power switch 260 will be in the OFF state.

(5. A Case where the Branch Device 10 is not Connected)

In the case where the branch device 10 is not connected, the potential of the connection point “j” is pulled down to GND by the pull-down resistor 252, therefore, the output of the first comparator 257 is “L” level as the GND is lower than the first reference voltage “Vcc (⅓)”, and the power switch control signal F as the output of the window comparator 253 is “L” level. As a result, the power supply to the branch device 10 in the power switch 260 will be in the OFF state.

(6. A Case where Neither of the Pull-Up Resistor 30 and the Short Resistor 40 is not Connected)

This case corresponds to the case of “5” (the case where the branch device 10 is not connected), therefore, the power supply to the branch device 10 in the power switch 260 will be in the OFF state.

As described above, in the display device 200 according to the embodiment, whether power supply from the display device 200 is necessary for the connected branch device 10 is determined by evaluating the voltage of the connection point “j” to be evaluated by comparison with two types of reference voltages in the level evaluation circuit 250, which can drastically reduce the number of steps for determination. That is, in the typical example, complicated branch processing (FIG. 2) is necessary in accordance with the detection result of connection/disconnection of the branch device 10 or the detection result of the power ON/OFF state of the branch device 10 by the device connection/power ON detection unit 130, however, such branch processing is not necessary in the display device 200 according to the present embodiment, and a proper determination result can be obtained only by switching the determination control signal E to “L” level when the power of the display device 200 is turned on as shown in FIG. 4. Accordingly, the determination can be made at higher speed as compared with the typical example. Particularly, in the case where the branch device 10 is the device to which power has to be supplied from the display device 200, it is possible to reduce time from the power ON of the display device 200 to the activation of the branch device 10.

### Second Embodiment

Next, a second embodiment of the present disclosure will be explained.

In the second embodiment, a delay circuit is added to a subsequent stage of the level evaluation circuit 250 in the display device 200 according to the first embodiment in order to eliminate sudden fluctuation components from the output of the level evaluation circuit 250 when the potential of the connection point “j” fluctuates largely, for example, from “H” level to “L” level at the time of connection/disconnection of the branch device 10 or at the time of switching the power ON/OFF of the branch device 10.

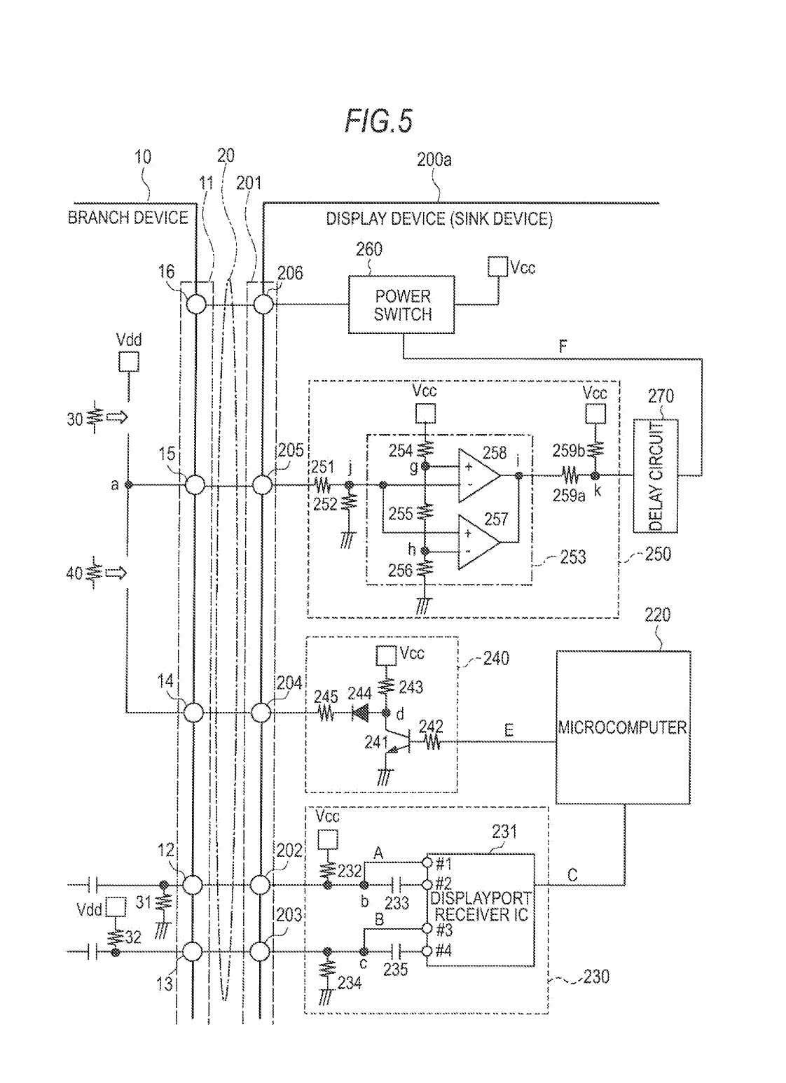

FIG. 5 is a diagram showing a configuration of a DisplayPort connection portion between a display device according to the second embodiment and a branch device connected thereto.

As shown in the drawing, a delay circuit 270 is provided between the level evaluation circuit 250 and the power switch 260 in a display device 200a according to the embodiment.

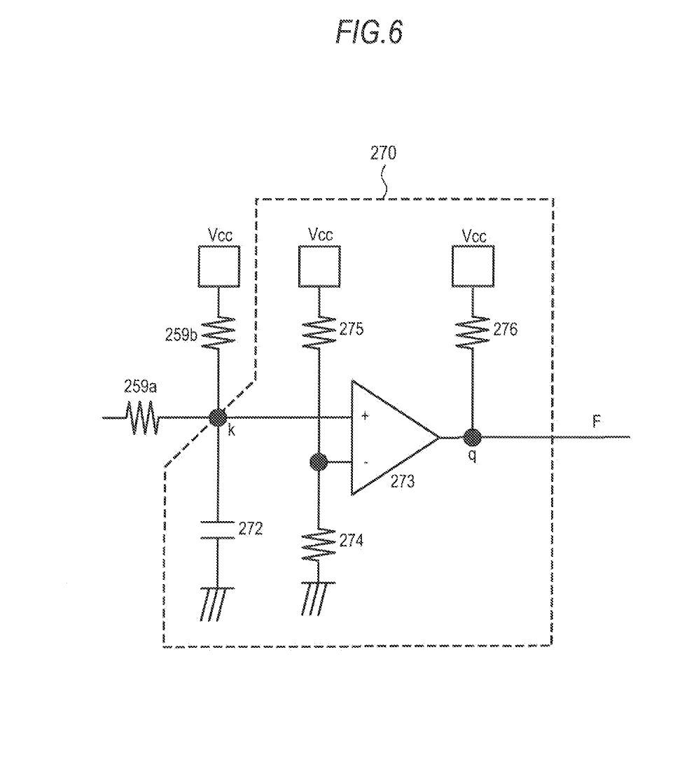

FIG. 6 is a diagram showing a configuration example of the delay circuit 270. The delay circuit 270 includes a capacitor 272 and a comparator 273 forming a low-pass filter together with the protection resistor 259a in the level evaluation circuit 250. The output of the low-pass filter is applied to a positive input terminal of the comparator 273. A given reference voltage generated by the ratio between the resistor 274 and the resistor 275 is applied to a negative input terminal of the comparator 273. The comparator 273 outputs the power switch control signal F in “H” level when the output voltage of the low-pass filter is higher than the given reference voltage. A connection point “q” between the output terminal of the comparator 273 and the power switch 260 is connected to the internal power source Vcc through a pull-up resistor 276.

The delay circuit 270 having the above configuration is added, thereby eliminating sudden fluctuation components from the output of the level evaluation circuit 250 when the potential of the connection point “j” fluctuates largely at the time of connection/disconnection of the branch device 10 or at the time of switching the power ON/OFF of the branch device 10, as a result, reliability can be improved.

### Third Embodiment

As explained in the description of the first embodiment, the resistance value of the pull-down resistor 252 in the level evaluation circuit 250 is set to be sufficiently higher than the resistance value of the pull-up resistor 30 connected to the branch device 10 for evaluating the voltage to be evaluated by comparison with two types of reference voltages in the window comparator 253. However, there is a danger that leak current in the window comparator 253 affects operations of the window comparator 253 in this case.

In the display device according to the third embodiment, measures are taken for preventing effects to operations of the window comparator 253 due to the leak current.

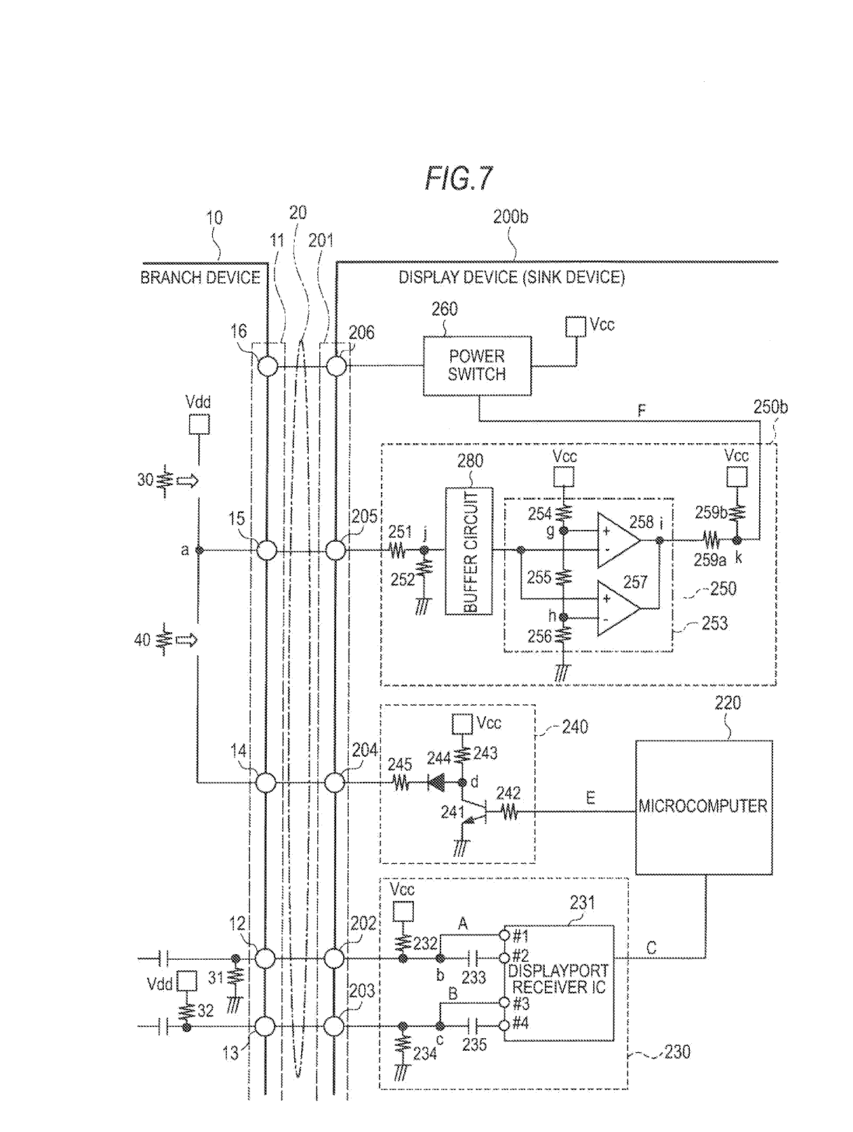

FIG. 7 is a diagram showing a configuration of a DisplayPort connection portion between a display device according to the third embodiment and a branch device connected thereto.

As shown in the drawing, a buffer circuit 280 is connected between the connection point “j” between the protection resistor 251 and the pull-down resistor 252 in a level evaluation circuit 250b and the window comparator 253.

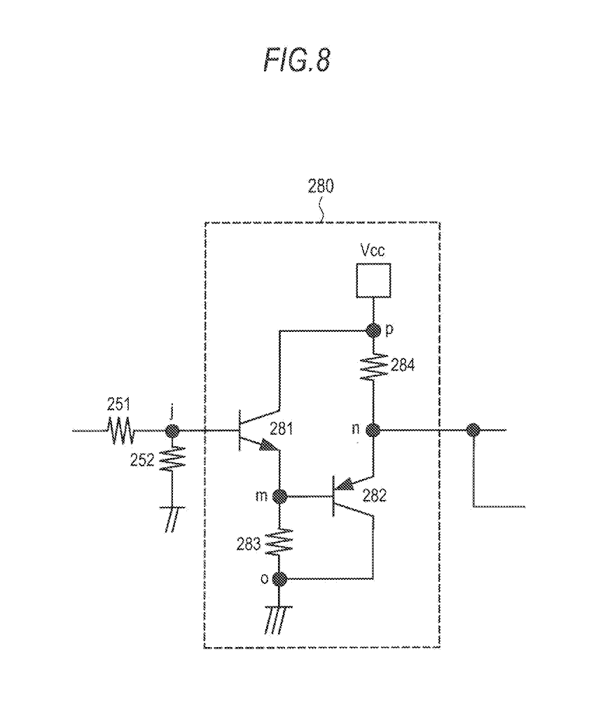

FIG. 8 is a diagram showing a configuration example of the buffer circuit 280. The buffer circuit 280 includes an NPN transistor 281, a PNP transistor 282, a resistor 283, a resistor 284 and so on. A base of the NPN transistor 281 is connected to the connection point “j” between the protection resistor 251 and the pull-down resistor 252. A collector of the NPN transistor 281 is connected to the internal power source Vcc. An emitter of the NPN transistor 281 is connected to GND through the resistor 283 and a connection point “m” between the emitter of the NPN transistor 281 and the resistor 283 is connected to a base of the PNP transistor 282. An emitter of the PNP transistor 282 is connected to the internal power source Vcc through the resistor 284. A collector of the PNP transistor 282 is connected to GND. Additionally, a connection point “n” between the emitter of the PNP transistor 282 and the resistor 284 is connected to the input terminal of the window comparator 253.

The buffer circuit 280 having the above configuration is provided between the connection point “j” between the protection resistor 251 and pull-down resistor 252 in the level evaluation circuit 250 and the window comparator 253, thereby suppressing fluctuation of the input voltage to the window comparator 253 due to leak current as well as preventing a malfunction of the level evaluation circuit 250.

### Fourth Embodiment

Generally, there exists a stand-by state as a state of the display device in addition to a normal power-on state. In the stand-by state, for example, a black screen is displayed or the screen is extinguished to thereby save power. The transition from the power-on state to the stand-by state is performed by, for example, the input of a command for transition to the stand-by state by the source device through the branch device, or the detection that there is no signal input from the branch device for a set time continuously. Conversely, the display device is returned to the power-on state by the input of a command for returning from the stand-by state to the normal power-on state by the source device, the signal input from the source device, an operation of turning on the power of the display device and so on through the branch device under the stand-by state.

As described above, in the display device which can be switched to the stand-by state, the microcomputer may perform control described below in accordance with transition between the power-on state and the stand-by state.

1. The microcomputer sets the level of the determination control signal E to “H” so that power supply to the branch device is OFF at the transition from the power ON state to the standby state. Accordingly, it is possible to stop wasteful power supply from the display device to the branch device when the branch device or the source device is in a nonoperational state.

2. The microcomputer executes determination whether the branch device is a device to which power has to be supplied from the display device or not again by switching the level of the determination control signal E to “L” at the transition from the stand-by state to the power ON state. Accordingly, in the case where the source device is a device to which power has to be supplied from the display device, the power supply from the display device to the branch device can be restarted automatically when the source device is in the operational state.

### Modification Example 1

Assume a case where the typical display device shown in FIG. 1 has video interfaces of plural types of standards (for example, DVI: Digital Visual Interface, HDMI: High-Definition Multimedia Interface, and so on) including DisplayPort. Also in the case where interfaces in standards other than DisplayPort are used for connection of the branch device 10 in the above display device, the DisplayPort IC 131 operates so as to constantly monitor connection/disconnection of the branch device 10, therefore, wasteful power is consumed. A means for suppressing the wasteful power consumption will be explained.

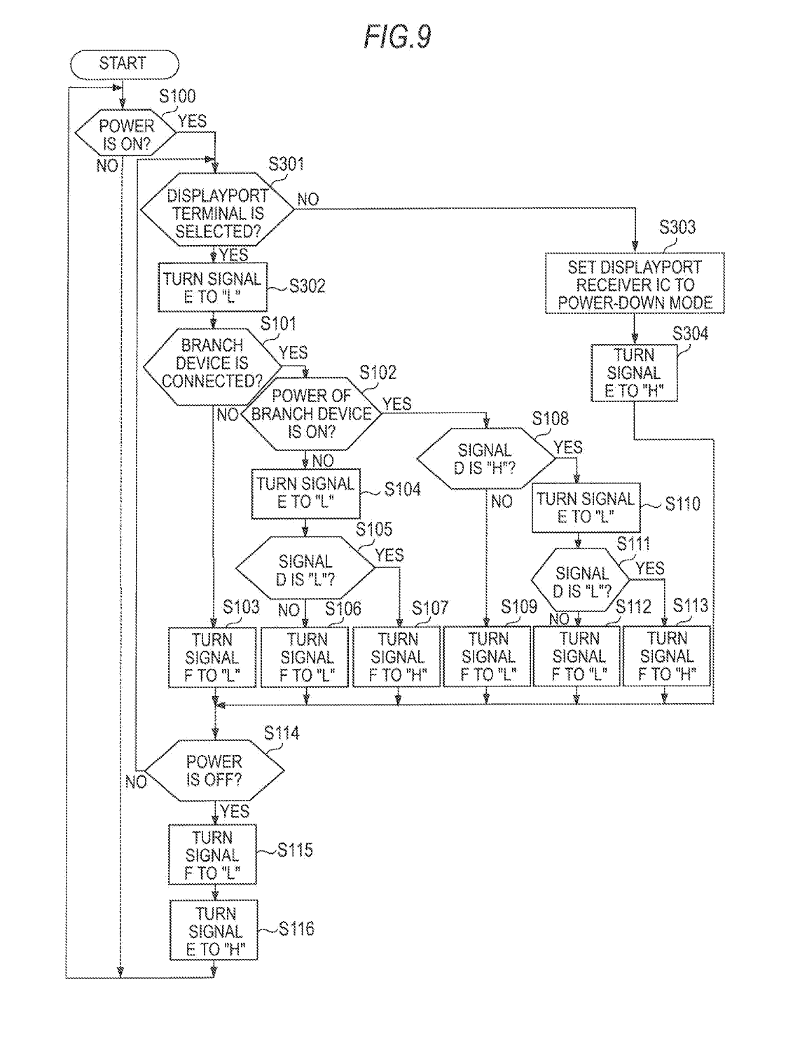

FIG. 9 is a flowchart in the case where the means is applied to the typical display device 100 of FIG. 1.

When the power of the display device 100 is turned on, operation power is supplied to respective units including the microcomputer 120, the DisplayPort receiver IC 131 in the device connection/power ON detection unit 130 and so on. When the microcomputer 120 detects that the power of the display device 100 is turned on (Y in Step S100), the microcomputer 120 determines whether the use of the DisplayPort terminal is selected in an internal setting of the display device 100 (Step S301).

When the microcomputer 120 determines that the use of the DisplayPort terminal is selected (Y in Step S301), the microcomputer 120 switches the level of the determination control signal E from “H” to “L” (Step S302) and allows the device connection/power ON detection unit 130 to detect whether the branch device 10 is connected or not (Step S101). Subsequent operations are the same as FIG. 2.

On the other hand, when the microcomputer 120 determines that the use of the DisplayPort terminal is not selected (N in Step S301), the microcomputer 120 sets the DisplayPort receiver IC 131 to a power-down mode (Step S303). When the power-down mode is set, the DisplayPort receiver IC 131 is in an operation-stop state even when a power button of the display device 100 is pressed and the display device 100 is in the power-on state. Therefore, the power consumption amount of the DisplayPort receiver IC 131 will be approximately “0 (zero)”. After that, the level of the determination control signal E is maintained when it is “H” level and is switched to “H” when it is “L” level (Step S304). After that, the microcomputer 120 moves to the detection of power-OFF of the display device 100.

### Modification Example 2

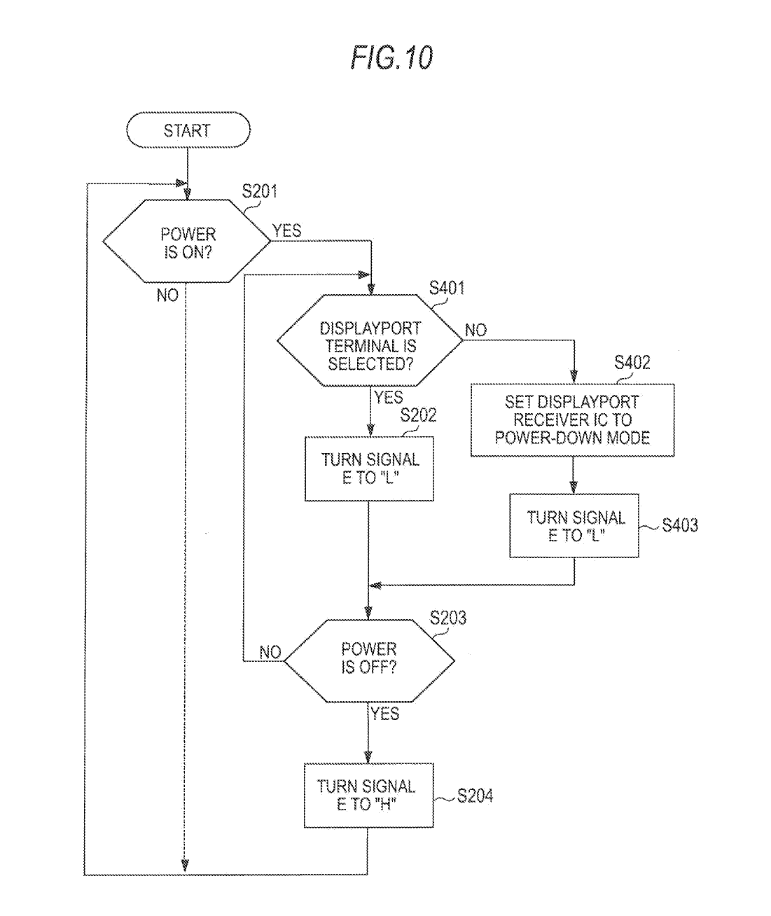

The processing of the modification example 1 can be also applied to the display device 200 according to the first embodiment. FIG. 10 shows a flowchart in the case where the processing of the modification example 1 is applied to the display device 200 according to the first embodiment.

When the microcomputer 220 detects that the power of the display device 200 is turned on (Y in Step S201), the microcomputer 220 determines whether the use of the DisplayPort terminal is selected in the internal setting of the display device 200 (Step S401).

When the microcomputer 220 determines that the use of the DisplayPort terminal is selected (Y in Step S401), the microcomputer 220 switches the level of the determination control signal E from “H” to “L” (Step S202). After that, when the microcomputer 220 detects that the power of the display device 200 is turned off (Y in Step S203), the microcomputer 220 switches the level of the determination control signal E from “L” to “H” (Step S204).

On the other hand, when the microcomputer 220 determines that the use of the DisplayPort terminal is not selected (N in Step S401), the microcomputer 220 sets a DisplayPort receiver IC 231 to the power-down mode (Step S402). Subsequently, the microcomputer 220 allows the level of the determination control signal E to be maintained when it is “H” level and switches the level to “H” when it is “L” level (Step S403). After that, the microcomputer 220 moves to the processing of detecting the power-OFF of the display device 200 (Step S204).

The internal setting concerning whether the DisplayPort terminal is used or not in the display device 200 is sometimes changed while the power of the display device 200 is ON. When the setting of not using the DisplayPort terminal is changed to the setting of using the terminal while the power of the display device 200 is ON, the microcomputer 220 immediately changes the level of the determination control signal E from “H” to “L” (Step S202), and starts determination whether power supply to the branch device 10 is necessary or not. When the setting of using the DisplayPort terminal is changed to the setting of not using the terminal while the power of the display device 200 is ON, the microcomputer 220 immediately sets the DisplayPort receiver IC 231 to the power-down mode (Step S402) and switches the level of the determination control signal E from “L” to “H” (Step S403).

In the display devices according to the modification example 1 and the modification example 2, the DisplayPort receiver ICs 131 and 231 are set to the power-down mode when the power of the display device is turned on in the case where the internal setting of not using the DisplayPort terminal is set, thereby preventing wasteful power consumption.

### Modification Example 3

Though ON/OFF of the power supply to the branch device is switched by using the power switch in the above embodiment, a power IC can be used instead of the power switch. When the power IC is used instead of the power switch, the voltage Vcc applied to the power switch can be connected to a different power supply voltage Vcc2.

Both in the power switch and the power IC, there exist “H” level and “L” level as logical levels of the operation control signal for allowing the operation state to be ON. The relation between the logical level of the power switch control signal F inputted from the level evaluation circuit 250 and ON/OFF of the power supply can be arbitrarily defined in accordance with the selection of the logical levels, therefore, the relation of positive/negative of respective input terminals of the first comparator 257 and the second comparator 258 in the window comparator 253 can be reversed.

The present disclosure is not limited to the above embodiment and various modifications can be made within a scope not departing from the gist of the present disclosure.

The present disclosure contains subject matter related to that disclosed in Japanese Priority Patent Application JP 2011-038494 filed in the Japan Patent Office on Feb. 24, 2011, the entire content of which is hereby incorporated by reference.

What is claimed is:

1. A display device comprising:
a second connector which can be connected to a first connector of a branch device having the first connector for connecting to a display device as a sink device, in which a pull-up resistor is connected between a first internal power source in the branch device and a first terminal predetermined in the first connector when power supply from the display device is not necessary for the branch device, and a short resistor is connected between the first terminal and a second terminal predetermined in the first connector when power supply from the display device is necessary;
a determination signal supply circuit applying a signal for determination to the second terminal of the connected branch device; and
a level evaluation circuit determining whether the branch device is a device to which power has to be supplied from the display device or not by evaluating a voltage appearing in the first terminal at the time of applying the signal for determination to the second terminal by comparison with two types of reference voltages which are different to each other set in advance within a range higher than a GND voltage and lower than a voltage of a second internal power source of the device itself.

2. The display device according to claim 1,
wherein the level evaluation circuit determines that the branch device is the device to which power has to be supplied from the display device when the voltage appearing in the first terminal is within a range of two types of reference voltages, and determines that the branch device is the device to which power does not have to be supplied from the display device when the voltage in the first terminal is out of the range of two types of reference voltages, and
the display device further comprising:
a first voltage dividing resistor forming a first resistance voltage dividing circuit in cooperation with the short resistor, which sets the voltage appearing in the first terminal at the time of applying the determination signal to the second terminal to the range of two types of reference voltages when the short resistance is connected; and
a second voltage dividing resistor forming a second resistance voltage dividing circuit in cooperation with the first voltage dividing resistor, which sets the voltage appearing in the first terminal at the time of applying the determination signal to the second terminal so as to be out of the range of two types of reference voltages when the first internal power source in the branch device is ON as well as the pull-up resistor is connected.

3. The display device according to claim 1, further comprising:
a switch unit switching ON/OFF of the power supply to the connected branch device,
wherein the level evaluation circuit supplies a first switch control signal for turning on the power supply to the branch device to the switch unit when the voltage appearing in the first terminal is within the range of two types of reference voltages, and supplies a second switch control signal for turning off the power supply to the branch device to the switch unit when the voltage in the first terminal is out of the range of two types of reference voltages.

4. The display device according to claim 3, further comprising:
a delay circuit provided between the level evaluation circuit and the switch unit.

5. The display device according to claim 1,
wherein the level evaluation circuit includes a buffer circuit for preventing voltage variation of the first terminal due to leak current.

6. The display device according to claim 1, further comprising:
a control unit controlling the determination signal supply circuit to stop the supply of the determination signal at the transition from a power-on state to a stand-by state, and controlling the determination signal supply circuit to restart the supply of the determination signal at the transition from the stand-by state to the power-on state.

7. A power-supply necessity determination method of a branch device connected to the display device, comprising:
connecting the display device to a first connector of the branch device having the first connector for connecting to the display device as a sink device, in which a pull-up resistor is connected between a first internal power source in the branch device and a first terminal predetermined in the first connector when power supply from the display device is not necessary for the branch device, and a short resistor is connected between the first terminal and a second terminal predetermined in the first connector when power supply from the display device is necessary;
applying a signal for determination from the display device to the second terminal of the connected branch device;
taking a voltage appearing in the first terminal into a level evaluation circuit in the display device; and
determining whether the branch device is a device to which power has to be supplied from the display device or not by evaluating the voltage in the first terminal by comparison with two types of reference voltages which are different to each other set in advance within a range higher than a GND voltage and lower than a voltage of a second internal power source of the device itself.
